(19) United States
(12) Patent Application Publication
(10) Pub. No.: US 2008/0197432 A1
(43) Pub. Date: Aug. 21, 2008

(54) Microchip Assembly Produced by Transfer Molding

(75) Inventors: Johannes Wilhemus Weekamp, Beek en Donk (NL); Will Ansems, Eindhoven (NL); Hedzer De Boer, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/994,441

(22) PCT Filed: Jun. 28, 2006
(86) PCT No.: PCT/IB2006/052148

§ 371 Date: Jan. 2, 2008

(30) Foreign Application Priority Data
Jul. 5, 2005 (EP) 05106083.8

(51) Int. Cl. H01L 29/82; H01L 21/56; H01L 29/00; B29C 45/14

(52) U.S. Cl. 257/421; 264/510; 438/127; 257/414; 257/E21.502; 257/E29.323; 257/E29.001

(57) ABSTRACT

The invention relates to a microchip assembly and an associated general production process, wherein an originally unshaped first component (1) is forged against the surface of a transfer molding form by an injected molten second component (5). The first component (1) may particularly comprise electrical tracks (3) on a carrier layer, said carrier layer being removed after the solidification of the injected material. According to a preferred embodiment, a microchip (8) is bonded to the electrical tracks (3) and then embedded in a filling (10). The electrical tracks (3) preferably lead from the front side (11) of the microchip (8) to the back side of the assembly, where they can be connected to external circuits. A sensitive front side (11) of a sensor microchip (8) can thus be placed very close to the front plane of the whole assembly, making the assembly apt for biosensor applications.

The invention relates to a method for the production of an article which comprises the junction of a three-dimensionally shaped outer layer of a first component and a body of a second component. Moreover, the invention comprises a microchip assembly and a microfluidic device which are produced according to the aforementioned method.

In the WO 2005/038911 A1, a microchip assembly is described with a sensor microchip being placed behind a hole in an insulating plate. When such an assembly is used as a biosensor, a sample fluid has to dive into said hole to reach the sensitive front side of the sensor chip. This has the disadvantage to produce regions of low or stagnant flow and a possible loss of material to the walls.

Based on this situation, it was an object of the present invention to provide means that allow the production of biosensors with sensor microchips which can be better contacted by sample fluids.

This object is achieved by a method according to claim 1, a microchip assembly according to claim 6, and a microfluidic device according to claim 10. Preferred embodiments are disclosed in the dependent claims.

According to its first aspect, the invention relates to a method for the production of an article, wherein said article shall comprise the junction or linkage of a three-dimensionally shaped outer layer of a first component and an internal body of a second component. Besides these general structural features, the article and its intended purpose may be quite arbitrary. The article may for example be a tool, a household appliance, a design article, a toy, a casing, or especially a microchip assembly as it will be described in more detail below. The method for the production of such an article comprises the following steps:
a) placing a yet unshaped first component into a transfer molding form;
b) injecting the (typically molten) material of the second component into the transfer molding form from an injection side of the unshaped first component in such a way that the first component is pressed against the inner surface of the form and thus assumes the three-dimensional shape of said surface;
c) solidifying the material of the second component, thereby attaching the second component to the shaped first component and (if necessary) fixing the generated shape of the first component.

The unshaped first component that is used in step a) may typically be a flat (preprocessed) material, for example a single-layer or multilayer metal sheet. The transfer molding form is as usual a negative image of the shape of the article to be produced. A transfer molding form is filled by a material under pressure with an ability to flow, typically a molten material, wherein said material assumes a negative image of the form and keeps this shape after solidification. According to the method described above, this known process is modified by injecting the material of the second component into the transfer molding form from one side (called the “injection side”) of the already present unshaped first component. The filling process then simultaneously generates the desired three-dimensional shape of the first component. As usual, the transfer molding form has to be constructed such that it can be evacuated before the injection or that air can leave the form during the injection process.

The injected material must have enough power to deform and forge the first component. It is therefore typically injected with a pressure of more than 10 bar, preferably more than 30 bar, most preferably more than 50 bar.

The material of the second component is typically a (homogeneous or heterogeneous) plastic, for example a reactive epoxy resin or a thermoplastic like a polycarbonate or a cyclic olefine polymer (COP).

According to a further development of the method, the unshaped first component is clamped or fixed between two parts of the transfer molding form before and/or while the material of the second component is injected in step b). The fixation guarantees that the first component assumes and keeps a desired position relative to the transfer molding form. Once the first component is immobilized by the injected material pressing it against the surface of the form, the clamping between the two parts of the transfer molding form may be released (for instance by retracting a movable part of the transfer molding form). The clamping may however also be continued throughout the whole process resulting in an area of the first component that will not be contacted by the material of the second component.

As was already mentioned, the first component may be a homogeneous material like a single-layer metal sheet. In a preferred embodiment of the invention, the first component comprises a carrier layer at the side opposite to the injection side, wherein said carrier layer is at least partially removed after the solidification in step c). Because it is opposite to the injection side, the carrier layer comes into contact with the transfer molding form and will thus be a part of the outer surface of the produced article. The carrier layer will therefore be accessible from outside which later on allows its selective removal. Preferred materials for the carrier layer are metals like aluminum or copper. If the carrier layer consists of a metal (e.g. copper), its removal may be achieved by mechanical procedures like milling and/or chemical procedures like etching. The thickness of the carrier layer typically ranges from 10 μm to 100 μm. The carrier layer allows to process fragile and/or one-dimensionally extending structures by providing an temporary basis therefore.

It was already mentioned that the article may particularly be a microchip assembly. In this case, the first component preferably comprises electrical tracks or leads to which a microchip is bonded after the solidification in step c). Due to the deformation step of the process, the electrical tracks may be realized in any desired three-dimensional shape. Moreover, the electrical tracks may optionally be created on a temporary carrier layer of the kind mentioned above.

In the aforementioned embodiment of a microchip assembly, the microchip is preferably disposed in a hole through the article with the electrical tracks leading from the front side of the microchip to the back side of the article. In this case, the front side of the microchip is by definition oriented towards the front side of the article and the back side of the microchip to the back side of the article. The microchip is therefore contacted as usual at its front side (where bonding pads are typically provided), while the complete article may be contacted at its back side. The front side of the whole article may therefore be substantially flat. This is particularly advantageous in biosensor applications in which a sensitive front side of a sensor microchip has to be contacted by some sample fluid streaming along the front plane of the microchip assembly.

The invention further relates to a microchip assembly with a front side and back side, the assembly comprising the following components:
a) a microchip;
b) a filling that embeds at least partially the microchip;
c) a substrate that embeds at least partially the filling, wherein filling and substrate may particularly contain identical materials;
d) electrical tracks leading from the front side of the assembly, where they are bonded to the microchip, along the interface between the filling and the substrate to the back side of the assembly.

The microchip assembly embeds a microchip securely in a filling and a substrate. Moreover, it has the advantage that the electrical tracks contact the microchip at its front side while they themselves can be contacted at the back side of the assembly, thus keeping the front side of the assembly free from bulky external connections.

According to a preferred embodiment, the front side of the microchip assembly comprises a hole through which the front side of the microchip is accessible. As the electrical tracks lead from the front side of the microchip to the back side of the assembly, it is possible to dispose the front side of the microchip approximately in the front plane of the whole assembly. The front side of the microchip may therefore be readily contacted by sample materials, making this arrangement apt for (bio-)sensor applications.

The microchip of the assembly may particularly comprise a magnetic field sensor. In this case, the assembly can be used for the detection of particles labeled with magnetic beads.

The microchip assembly may preferably be produced by a method of the kind described above, i.e. by forming an unshaped first component during the injection of a material of a second component in a transfer molding form.

The invention further comprises a microfluidic device with a microchip assembly of the kind described above. Such a microfluidic device may particularly constitute a biosensor for the investigation of fluid biochemical samples.

These and other aspects of the invention will be apparent from and elucidated with reference to the embodiment(s) described hereinafter.

In the following the invention is described by way of example with the help of the accompanying drawings in which:

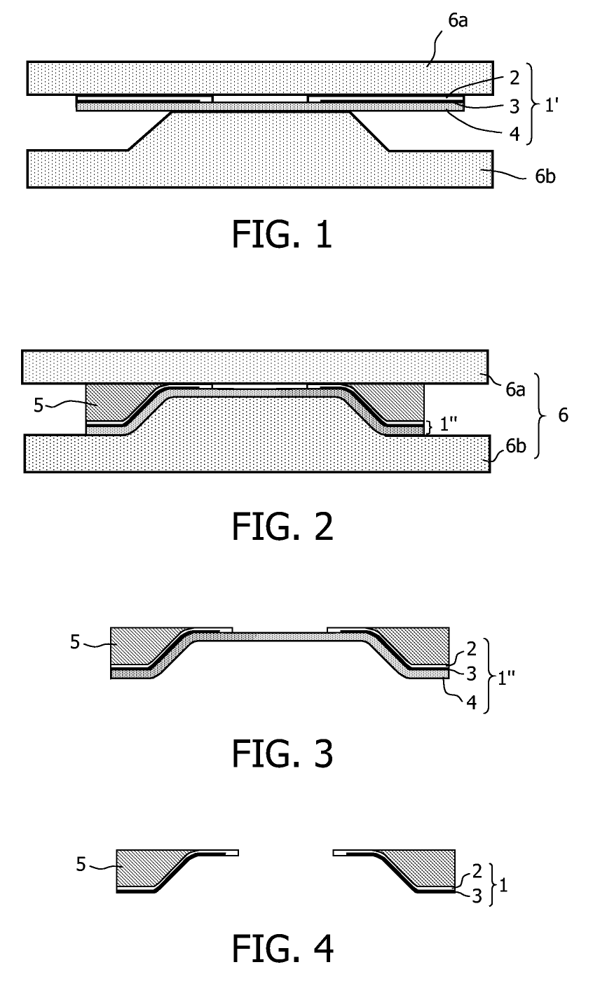

FIG. 1 shows a lateral view of a section through a transfer molding form for the production of a biosensor microchip assembly, wherein an unshaped first component is clamped between a top and a bottom part of the form;

FIG. 2 shows the system of FIG. 1 after the injection of a second component and the resulting deformation of the first component;

FIG. 3 shows the article produced after solidification of the second component and the removal from the transfer molding form of FIG. 2;

FIG. 4 shows the article of FIG. 3 after removal of the carrier layer of the first component;

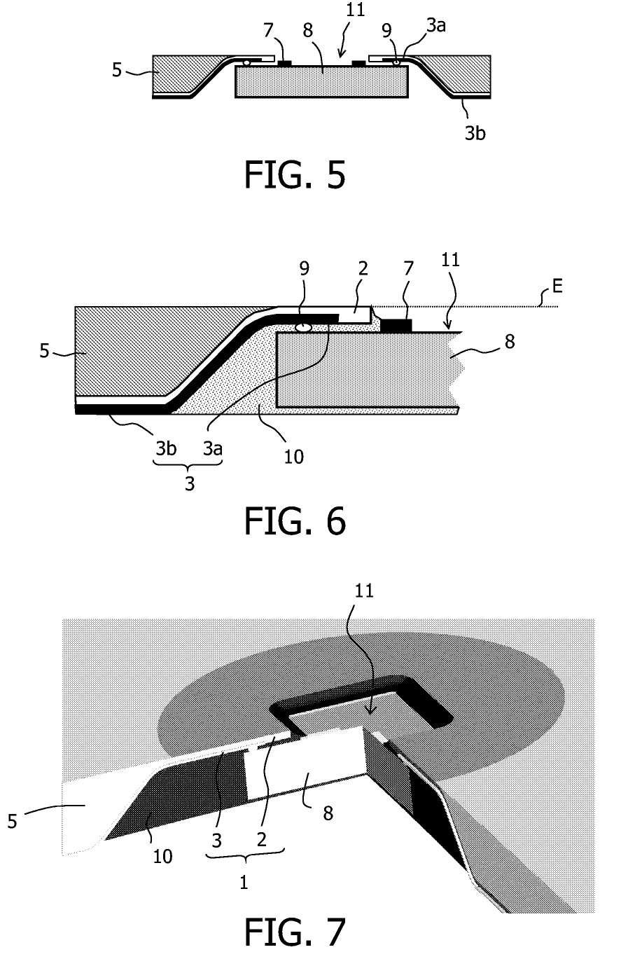

FIG. 5 shows the article of FIG. 4 after the bonding of a microchip to the electrical tracks of the first component;

FIG. 6 shows an enlarged view of the article of FIG. 5 after embedding the microchip in a filling;

FIG. 7 shows a perspective sectional view of a microchip assembly produced according to the steps illustrated in the previous Figures.

In the following, the production of a biosensor will be described as an example for the application of the present invention. The invention is however not restricted thereto and can readily be applied in many different areas.

Biosensors are becoming increasingly important in future, wherein low cost packaging is very important for disposable biosensors with electrical interconnections. One of the measuring principles of biosensors is the counting of labeled molecules. For example, the molecules may be labeled with magnetic beads which can be detected with a magneto-resistive sensor. These sensors are typically produced with a silicon wafer technology. Examples of such biochips are described in the WO 2005/010542 A2, WO 2005/010543 A1, and WO 2005/038911 A1, which are incorporated into the present application by reference. A disadvantage of these biochips is that the top surface of the sensor is at a distance from the top surface of the package, so that the fluid has to dive toward the sensor, i.e. the fluid needs to be guided along a corner and will encounter irregular structures. This can imply the need for a large fluid sample, imply regions of low or stagnant flow, and possibly loss of material to the walls. It is therefore preferred to make the distance between the top of the package and the sensitive front side of the sensor chip as small as possible. In the following, a method for the production of a microchip assembly that achieves this objective and overcomes the aforementioned difficulties will be described in more detail.

FIG. 1 schematically illustrates the first step of said method. An originally unshaped (i.e. flat) first component 1′ is provided which consists of a carrier layer 4 (typical thickness: 50-100 μm) with gold plated copper tracks 3 on its upper side. The tracks 3 are locally covered with a photosensitive insulating layer 2. The first component 1′ can be produced by any method known to a person skilled in the art. It is clamped between the flat underside of a top part 6a and an upstanding circular protrusion of the corresponding bottom part 6b of a transfer molding form 6.

FIG. 2 shows the transfer molding form 6 after the injection of a molten second component 5, which may for example be a plastic. An important feature of the process is that the second component 5 is injected between the upper part 6a of the transfer molding form 6 and the first component 1′, i.e. from an “injection side” of the first component (which is the side of the insulating layer 2 in this case). Due to the high pressure of the molding process (typically more than 50 bar) the thin substrate 1′ in forged around the protrusions of the bottom part 6b. At the same time, an intimate contact and a close junction between the injected second component 5 and the first, now three-dimensionally shaped component 1 results. The injection of the second component 5 may be performed through passages in the top part 6a that are not shown in the Figures.

After the solidification of the second component 5, the article shown in FIG. 3 can be removed from the transfer molding form.

In the next step, the carrier layer 4 is removed from the article because the mechanical stabilization of the tracks 3 is no longer necessary as they are now attached to the second component 5. The removal may for example by achieved by chemical etching, yielding the article of FIG. 4.

FIG. 5 shows how a sensor microchip 8 is attached via gold or solder bumps 9 to the front sided ends 3a of the electrical tracks 3, wherein the microchip 8 is disposed in the (circular) hole generated by the protrusion of the bottom part 6b of the transfer moulding form 6. The back sided ends 3b of the electrical tracks 3 can be used as terminals for external connections.

In the next step, the microchip 8 is embedded in an under-filling 10, wherein an optional circumferential seal-ring 7 on the front side 11 of the microchip 8 prevents an overflow of said filling 10. FIG. 6 shows this in an enlarged section through one half of the resulting microchip assembly. FIG. 7 depicts a similar section in a three-dimensional perspective view. Typical dimensions of the shown microchip assembly are:

Sensor chip area: 1.4×1.5 mm

30 bond pads (9) with pitch of 150 μm

Thickness of leads (3): 10 μm

total thickness of interconnections above sensor-surface (11): <30 μm.

An advantage of the described microchip assembly is that the front side 11 of the sensor microchip 8 is very close to the front plane E of the whole assembly, because only the bumps 9, the electrical tracks 3, and the outer insulating layer 2 extend above the front side 11 of the microchip 8. Sensitive circuits at this front side (e.g. wires for the generation and/or a Giant Magneto Resistances GMR for the detection of a magnetic field) can therefore be brought very close to front plane, and a sample fluid needs not to dive into a recess.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1-10. (canceled)

11. Method for the production of an article which comprises the junction of a three-dimensionally shaped outer layer of a first component and a body of a second component, the method comprising the following steps:
a) placing the unshaped first component, which comprises a carrier layer at the side opposite to an injection side, into a transfer molding form;
b) injecting the material of the second component into the transfer molding form from the injection side of the unshaped first component in such a way that the first component is pressed against the inner surface of the form and assumes the three-dimensional shape thereof;
c) solidifying the material of the second component;
d) removing the carrier layer of the first component at least partially after the solidification.

12. Method for the production of an article which comprises the junction of a three-dimensionally shaped outer layer of a first component and a body of a second component, the method comprising the following steps:
a) placing the unshaped first component, which comprises electrical tracks, into a transfer molding form;
b) injecting the material of the second component into the transfer molding form from an injection side of the unshaped first component in such a way that the first component is pressed against the inner surface of the form and assumes the three-dimensional shape thereof;
c) solidifying the material of the second component;
d) disposing a microchip in a hole of the article and bonding it to the tracks after the solidification, wherein the tracks lead from the front side of the microchip to the back side of the article.

13. The method according to claim 11, characterized in that the unshaped first component is clamped between two parts of the transfer molding form before and/or during the injection in step b).

14. A microchip assembly with a front side and a back side, comprising:
a) a microchip;
b) a filling that embeds at least partially the microchip;
c) a substrate that embeds at least partially the filling;
d) electrical tracks leading from the front side of the assembly, where they are bonded to the microchip, along the interface between the filling and the substrate to the back side of the assembly;
e) a hole in the front side of the assembly through which the front side of the microchip is accessible.

15. The microchip assembly according to claim 14, characterized in that the microchip comprises a magnetic field sensor.

16. The microchip assembly according to claim 14, characterized in that it is produced by a method for the production of an article which comprises the junction of a three-dimensionally shaped outer layer of a first component and a body of a second component, the method comprising the following steps:
a) placing the unshaped first component, which comprises a carrier layer at the side opposite to an injection side, into a transfer molding form;
b) injecting the material of the second component into the transfer molding form from the injection side of the unshaped first component in such a way that the first component is pressed against the inner surface of the form and assumes the three-dimensional shape thereof;
c) solidifying the material of the second component;
d) removing the carrier layer of the first component at least partially after the solidification.

17. A microfluidic device, particularly a biosensor, comprising a microchip assembly according to claim 14.
